(19) United States
(12) Patent Application Publication
(10) Pub. No.: US 2015/0179841 A1
(43) Pub. Date: Jun. 25, 2015

(54) SOLAR CELL AND METHOD OF FABRICATING THE SAME

(71) Applicant: LG INNOTEK CO., LTD., Seoul (KR)

(72) Inventors: Myoung Seok Sung, Seoul (KR); Dae Jin Jang, Seoul (KR)

(73) Assignee: LG INNOTEK CO.M LTD., Seoul (KR)

(21) Appl. No.: 14/395,131

(22) PCT Filed: Apr. 18, 2013
(86) PCT No.: PCT/KR2013/003319

§ 371 Date: Oct. 17, 2014

(30) Foreign Application Priority Data
Apr. 18, 2012 (KR) 10-2012-0040263

(51) Int. Cl. H01L 31/0336; H01L 31/0296; H01L 31/0304; H01L 31/032

(52) U.S. Cl. CPC H01L 31/03365; H01L 31/032; H01L 31/0296; H01L 31/03044

(57) ABSTRACT

A solar cell according to the embodiment includes a light absorbing layer; a buffer layer on the light absorbing layer; a high resistance buffer layer on the buffer layer; and a window layer on the buffer layer, wherein the high resistance buffer layer has an energy bandgap higher than an energy bandgap of the window layer.

### TECHNICAL FIELD

The embodiment relates to a solar cell and a method of fabricating the same.

### BACKGROUND ART

Recently, as energy consumption is increased, solar cells to convert the solar light into electrical energy have been developed.

A solar cell (or photovoltaic cell) is a core element in solar power generation to directly convert solar light into electricity.

For example, if the solar light having energy greater than bandgap energy of a semiconductor is incident into a solar cell having the PN junction structure, electron-hole pairs are generated. As electrons and holes are collected into an N layer and a P layer, respectively, due to the electric field formed in a PN junction part, photovoltage is generated between the N and P layers. In this case, if a load is connected to electrodes provided at both ends of the solar cell, current flows through the solar cell.

In particular, a CIGS-based solar cell, which is a PN hetero junction apparatus having a substrate structure including a glass substrate, a metallic back electrode layer, a P-type CIGS-based light absorbing layer, a high-resistance buffer layer, and an N-type window layer, has been extensively used.

According to the related art, a TCO layer having high light transmittance and conductivity and used as a window layer is fabricated by depositing zinc oxide (i-ZnO), which is not doped with impurities, at a thickness of about 50 nm to 80 nm in order to prevent a shunt path and depositing Al doped zinc oxide on the zinc oxide in order to reduce damage to a lower layer. However, when the AZO and the BZO layers are deposited, aluminum and boron convert the high resistance property of ZnO into the conductive property through the heat and oxygen treatment, so that the shunt path is increased.

### DISCLOSURE OF INVENTION

### Technical Problem

The embodiment provides a solar cell which can prevent a shunt path to improve an electrical characteristic of the solar cell.

### Solution to Problem

According to the embodiment, there is provided a solar cell including a light absorbing layer; a buffer layer on the light absorbing layer; a high resistance buffer layer on the buffer layer; and a window layer on the buffer layer, wherein the high resistance buffer layer has an energy bandgap higher than an energy bandgap of the window layer.

### Advantageous Effects of Invention

According to solar cell of the embodiment, the phenomenon that the incident light is absorbed in the high resistance layer may be improved.

In addition, the high resistance buffer layer is prevented from being doped with Al or B upon the high temperature and oxygen treatment, so that an electrical characteristic may be improved.

Further, the high resistance buffer layer including boron nitride (BN) has a cubic structure similar to CdS, so that a mechanical mismatching may be prevented.

### BRIEF DESCRIPTION OF DRAWINGS

FIG. 1 is a sectional view showing a solar cell according to the embodiment; and

FIGS. 2 to 5 are views illustrating a process of fabricating a solar cell panel according to the embodiment.

### MODE FOR THE INVENTION

In the description of the embodiments, it will be understood that when a substrate, a layer, a film or an electrode is referred to as being “on” or “under” another substrate, another layer, another film or another electrode, it can be “directly” or “indirectly” on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

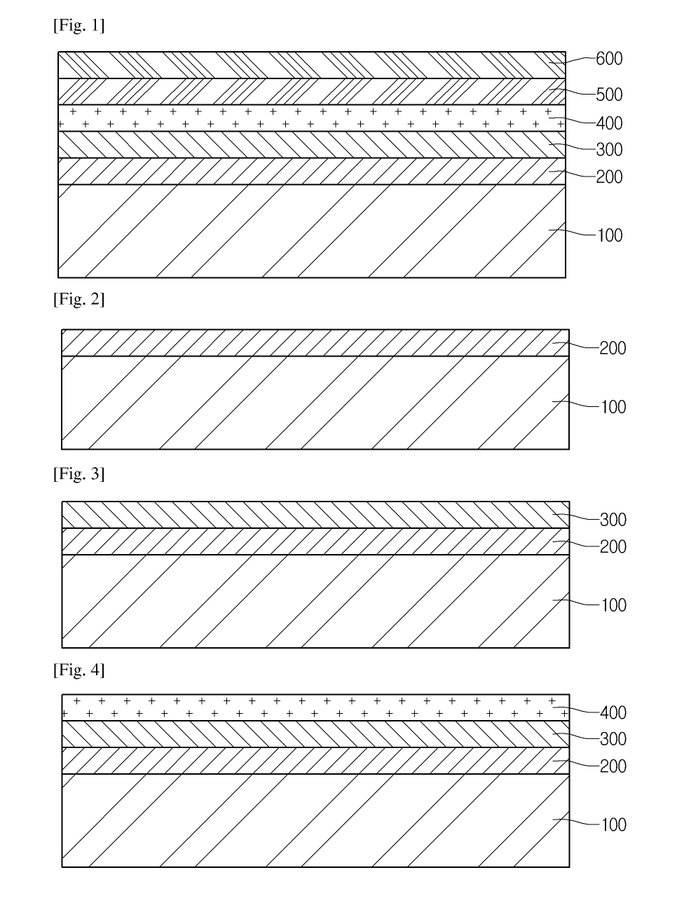

FIG. 1 is a sectional view showing a solar cell according to the embodiment. Referring to FIG. 1, the solar cell panel includes a support substrate 100, a back electrode layer 200, a light absorbing layer 300, a buffer layer 400, a high resistance buffer layer 500 and a window layer 600.

The support substrate 100 has a plate shape and supports the back electrode layer 200, the light absorbing layer 300, the buffer layer 400, the high resistance buffer layer 500 and the window layer 600.

The support substrate 100 may be an insulator. The support substrate 100 may be a metal substrate. In addition, the support substrate 100 may be formed of stainless steel (SUS, STS). The support substrate 100 may be identified with various symbols according to a component ratio of materials included in the support substrate 100 and may include at least one of C, Si, Mn, P, S, Ni, Cr, Mo and Fe. The support substrate 100 may be flexible.

The back electrode layer 200 is formed on the support layer 100. The back electrode layer 200 is a conductive layer. The back electrode layer 200 transfers charges produced in the light absorbing layer 300 of the solar cell, thereby allowing current to flow to the outside of the solar cell. The back electrode layer 200 must represent higher electric conductivity and lower resistivity in order to perform the above function.

In addition, the back electrode layer 200 must maintain high-temperature stability when heat treatment is performed under the atmosphere of sulfur (S) or selenium (Se) required when a CIGS compound is formed. In addition, the back electrode layer 200 must represent a superior adhesive property with respect to the substrate 100 such that the back electrode layer 200 is prevented from being delaminated from the substrate 100 due to the difference in the thermal expansion coefficient between the back electrode layer 200 and the substrate 100.

The back electrode layer 200 may include any one of molybdenum (Mo), gold (Au), aluminum (Al), chrome (Cr), tungsten (W), and copper (Cu). Among them, Mo makes the lower difference in the thermal expansion coefficient from the substrate 100 when comparing with the other elements, so that the Mo represents a superior adhesive property, thereby preventing the above de-lamination phenomenon, and totally satisfying the characteristic required for the back electrode layer 200. The back electrode layer 300 may have a thickness in the range of 400 nm to 1000 nm.

The light absorbing layer 300 may be formed on the back electrode layer 200. The light absorbing layer 300 includes a P-type semiconductor compound. In more detail, the light absorbing layer 300 includes a group I-III-VI-based compound. For example, the light absorbing layer 400 may have a Cu(In,Ga)Se2 (CIGS) crystal structure, a Cu(In)Se2 crystal structure, or a Cu(Ga)Se2 crystal structure. The light absorbing layer 300 may have an energy bandgap in the range of 1.1 eV to 1.2 eV, and a thickness in the range of 1.5 μm to 2.5 μm

The buffer layer 400 is provided on the light absorbing layer 300. According to the solar cell having the light absorbing layer 300 including the CIGS compound, a P-N junction is formed between a CIGS compound thin film, which serves as a P-type semiconductor, and the window layer 600 which is an N-type semiconductor. However, since two materials represent the great difference in the lattice constant and the bandgap energy therebetween, a buffer layer having the intermediate bandgap between the bandgaps of the two materials is required to form the superior junction between the two materials.

The material used for forming the buffer layer 400 includes CdS and ZnS. Since the CdS is relatively superior to any other materials in the aspect of the solar cell generation efficiency, the CdS has been generally used. The buffer layer 400 may be formed at a thickness in the range of 50 nm to 80 nm.

The high-resistance buffer layer 500 may be disposed on the buffer layer 400. The high-resistance buffer layer 500 may include boron nitride. The high-resistance buffer layer 500 may have an energy bandgap in the range of about 5.3 eV to about 5.7 eV and a thickness in the range of 50 nm to 80 nm.

When the high resistance buffer layer 500 includes zinc oxide (i-ZnO), which is not doped with impurities, the high resistance buffer layer 500 has the energy bandgap of about 3.34 eV, so the solar light incident from the window layer having a bandgap in the range of 3.2 eV to 3.7 eV is absorbed in ZnO, so that the light may not reach the light absorbing layer. However, due to the boron nitride layer having the bandgap in the range of 4.8 eV to 5.2 eV, the phenomenon that the incident light is absorbed in the high resistance buffer layer may be reduced.

In addition, the high resistance buffer layer is prevented from being doped with Al or B upon the high temperature and oxygen treatment, so that an electrical characteristic may be improved.

Further, the high resistance buffer layer 500 including boron nitride (BN) has a cubic structure similar to CdS, so that a mechanical mismatching may be prevented.

The window layer 600 is disposed on the high resistance buffer layer 500. The window layer 600 is transparent and a conductive layer. The resistance of the window layer 600 is higher than that of the back electrode layer 200.

The window layer 600 includes oxide. For example, the window layer 600 may include zinc oxide, indium tin oxide (ITO), indium zinc oxide (IZO), Al doped zinc oxide (AZO) or Ga doped zinc oxide (GZO), and BZO (ZnO:B).

According to the solar cell of the embodiment, the phenomenon that the incident light is absorbed in the high resistance layer may be reduced.

In addition, the high resistance buffer layer is prevented from being doped with Al or B upon the high temperature and oxygen treatment, so that an electrical characteristic may be improved.

Further, the high resistance buffer layer 500 including boron nitride (BN) has a cubic structure similar to CdS, so that a mechanical mismatching may be prevented.

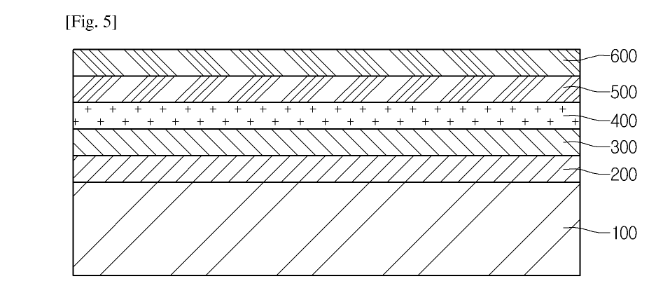

FIGS. 2 to 5 are sectional views illustrating a method of fabricating a solar cell panel according to the embodiment. A description about the fabricating method according to the embodiment refers to the solar cell described above. The description about the solar cell according to the previous embodiment will be incorporated in the description about the fabricating method according to the present embodiment.

Referring to FIG. 2, the back electrode layer 200 is formed on the support substrate 100. The back electrode layer 200 may be formed by depositing Mo. The back electrode layer 200 may be formed through a sputtering scheme. In addition, an additional layer such as an anti-diffusion layer may be interposed between the support substrate 100 and the back electrode layer 200.

Referring to FIG. 3, the light absorbing layer 300 is formed on the back electrode layer 200. The light absorbing layer 300 is formed by extensively using schemes, such as a scheme of forming a Cu(In,Ga)Se2 (CIGS) based-light absorbing layer 300 by simultaneously or separately evaporating Cu, In, Ga, and Se and a scheme of performing a selenization process after a metallic precursor film has been formed.

To the contrary, the sputtering process and the selenization process of using targets of Cu, In and Ga may be simultaneously performed. The CIS or CIG based light absorbing layer 300 may be formed through the sputtering process and the selenization process using only the Cu and In targets or the Cu and Ga targets.

Referring to FIG. 4, the light absorbing layer 300 is formed on the buffer layer 400. The buffer layer 400 may have the chemical composition of CdS and may be formed through PVD (Physical Vapor Deposition) or MOCVD (Metal-Organic Chemical Vapor Deposition), but the embodiment is not limited thereto.

Referring to FIG. 5, the high resistance buffer layer 500 is formed on the buffer layer 400. The high resistance buffer layer 500 may include BN. For example, the high resistance buffer layer 500 may have the chemical composition of BN.

The BN may be formed through a wet deposition (CSD deposition). A step coverage between the BN and the buffer layer 400 having the chemical composition of CdS may be increased, so that a shunt path phenomenon may be improved.

Next, the window layer 600 is formed on the high resistance buffer layer 500. The window layer 600 may include a transparent conductive material, such as the chemical composition of at least one of Al doped zinc oxide (AZO), indium tin oxide (ITO), indium zinc oxide (IZO), Ga doped zinc oxide (GZO), and BZO (ZnO:B), and may be formed through a deposition by a sputtering scheme.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a light absorbing layer;
a buffer layer on the light absorbing layer;
a high resistance buffer layer on the buffer layer; and
a window layer on the high resistance buffer layer,
wherein the high resistance buffer layer has an energy bandgap higher than an energy bandgap of the window layer.

2. The solar cell of claim 1, wherein the high resistance buffer layer has a chemical composition of BN.

3. The solar cell of claim 1, wherein the window layer has a chemical composition of AZO or BZO.

4. The solar cell of claim 1, wherein the high resistance buffer layer has a thickness in a range of 50 nm to 80 mil.

5. The solar cell of claim 1, wherein the high resistance buffer layer has an energy bandgap in a range of 5.3 eV to 5.7 eV.

6. The solar cell of claim 1, wherein the buffer layer has a chemical composition of CdS.

7. The solar cell of claim 1, wherein the high resistance buffer layer includes nitride.

8. The solar cell of claim 1, wherein the high resistance buffer layer includes boron nitride (BN).

9. The solar cell of claim 1, wherein the high resistance buffer layer includes a cubic structure.

10.-13. (canceled)

14. The solar cell of claim 1, wherein the light absorbing layer on the back electrode layer; and
the resistance of the window layer is higher than that the of the back electrode layer.
